(19) United States
(12) Patent Application Publication
(10) Pub. No.: US 2007/0047206 A1
(43) Pub. Date: Mar. 1, 2007

(54) Composite heat dissipating apparatus

(75) Inventors: Cheng-Chih Lee, Taoyuan Hsien (TW); Tsung-Lin Chen, Taoyuan Hsien (TW); Wen-Tsao Lee, Taoyuan Hsien (TW); Chin-Ming Chen, Taoyuan Hsien (TW)

Correspondence Address: BIRCH STEWART KOLASCH & BIRCH, PO BOX 747, FALLS CHURCH, VA, 22040-0747, US

(73) Assignee: DELTA ELECTRONICS, INC.

(21) Appl. No.: 11/365,879

(22) Filed: Mar. 2, 2006

(30) Foreign Application Priority Data
Aug. 24, 2005 (TW) 094128837

(51) Int. Cl. H05K 7/20

(52) U.S. Cl. 361/703

(57) ABSTRACT

A composite heat dissipating apparatus includes a heat pipe and at least two heat sinks. The heat sinks are connected to each other. A space for accommodating the heat pipe therein is formed at a connection between the heat sinks. Each of the heat sinks is integrally formed as a single piece.

This Non-provisional application claims priority under U.S.C.§ 119(a) on Patent Application No(s). 094128837, filed in Taiwan, Republic of China on Aug. 24, 2005, the entire contents of which are hereby incorporated by reference.

### BACKGROUND OF THE INVENTION

1. Field of Invention

The invention relates to a heat dissipating apparatus, and in particular to a composite heat dissipating apparatus.

2. Related Art

With the progress of the technology, the number of transistors in per unit area of the electrical element is getting larger and larger, and the heat generated as the transistors work is increased. On the other hand, the working frequency of the electrical element is getting higher and higher, so that the heat generated by the switch loss due to the on/off switching operations of the transistor mainly increases the total heat of the electrical element. If the heat is not dissipated properly, the operation speed of the chip is reduced, or even the lifetime of the chip is shortened. In order to enhance the dissipating effect of the electrical element, a heat sink is usually disposed at a heat source to dissipate the heat to external environment through the fins of the heat sink by way of natural or forced convection.

Heat pipe can transfer a lot of heat by a respectable distance with a very small cross-sectional area and a very small temperature difference and can operate without an external power supply. Also, under the consideration of no power provision and the economic consideration of the space utilization, and the heat pipe has become one of the widely used heat transfer elements in the electronic heat dissipating product. FIG. 1 is a schematic view of a conventional heat dissipating apparatus. As shown in FIG. 1, a heat dissipating apparatus 1 is composed of a plurality of heat dissipating fins 11, a heat pipe 12 and a base 13. The heat dissipating fins 11 are separately inserted into the heat pipe 12. Herein, it is to be specified that some heat dissipating fins 11, located near the heat pipe 12 and close to the base 13, are removed such that the arrangement of the heat dissipating fins 11, the heat pipe 12 and the base 13 can be clearly illustrated in the drawing. The heat dissipating fins 11, the heat pipe 12 and the base 13 are combined together by way of soldering. However, the conventional heat dissipating apparatus 1 has the following disadvantages. If the heat dissipating fins 11 are made of aluminum, the heat dissipating fins 11 have to be electroplated before soldering. As the result, this assembling method is not ideal under the considerations of the production efficiency and the electroplating cost. In addition, although the electroplating step can be omitted when the heat dissipating fins 11 are made of copper, the heat dissipating fins 11 are heavy and have a high cost because copper has the heavier property and the higher price than other materials.

Another method of assembling the heat dissipating apparatus is performed by way of pressing such that the heat dissipating fins 11 and the heat pipe 12 may be combined tightly. Then, the heat dissipating fins 11 and the heat pipe 12 are combined with the base 13 by way of soldering. This method, however, needs an additional pressing procedure.

Thus, no matter which one of the above-mentioned assembling methods, the heat dissipating fins 11, the heat pipe 12 and the base 13 have to be assembled by using a jig and other additional machines. Furthermore, the solder paste may not be coated smoothly and evenly, or even the solder paste may overflow such that the overall heat dissipating efficiency of the heat dissipating apparatus 1 is poor. Thus, it is an important subject of the invention to provide a heat dissipating apparatus with simplified manufacturing processes, reduced costs, and good heat dissipating efficiency.

### SUMMARY OF THE INVENTION

In view of the foregoing, the invention is to provide a composite heat dissipating apparatus with simplified manufacturing processes, reduced costs, and good heat dissipating efficiency.

To achieve the above, a composite heat dissipating apparatus of the invention includes a heat pipe and two heat sinks. The heat sinks are connected to each other. A space for accommodating the heat pipe therein is formed at a connection between the heat sinks. Each heat sink is integrally formed by, for example, aluminum extrusion. Herein, the heat pipe is U-shaped, C-shaped, lengthwise-shaped, M-shaped, or has any other shapes. A cross-sectional area of the heat pipe has a circular shape, an elliptic shape, a semi-circular shape, a rectangular shape, a triangular shape, a tetragonal shape, a trapezoidal shape, a regular polygonal shape or an irregular polygonal shape. Each heat sink has a plurality of fins, and the fins are separately arranged in a horizontal distribution, a vertical distribution, a slant distribution or a radial distribution.

The heat sinks of the composite heat dissipating apparatus are formed with slots at the connection, and the slots form the space. Alternatively, only one slot is formed on one of the heat sinks at the connection so as to form the space. The heat sinks have the same shape or different shapes, and the heat sinks are connected by way of riveting, screwing, soldering, adhering, embedding or engaging. The grease or a material serving as a heat conducting interface is coated in the space. The heat pipe contacts a heat source through a base or contacts the heat source directly so as to transfer heat generated by the heat source to the heat sinks directly.

To achieve the above, a composite heat dissipating apparatus of the invention includes a plurality of heat pipes and a plurality of heat sinks. In this case, the heat sinks are connected to one another. Spaces for respectively accommodating the heat pipes therein are formed at connections between every two adjacent heat sinks, and each of the heat sinks is integrally formed.

To achieve the above, a composite heat dissipating apparatus of the invention includes at least two heat pipes, a first heat sink and a second heat sink. In this case, the first heat sink and the second heat sink have different shapes but are connected to each another. At least two spaces for respectively accommodating the at least two heat pipes therein are formed at a connection between the first heat sink and the second heat sink, and each of the first heat sink and the second heat sink is integrally formed.

As mentioned hereinabove, each of the heat sinks of the composite heat dissipating apparatus according to the invention is integrally formed, and the heat pipe is disposed in the space formed in the heat sinks. As the result, when the heat sinks are combined together, no extra electroplating procedure or pressing procedure has to be performed. Compared to the prior art, the composite heat dissipating apparatus of the invention can enhance the production efficiency and decrease the manufacturing cost.

### BRIEF DESCRIPTION OF THE DRAWINGS

The invention will become more fully understood from the detailed description given herein below illustration only, and thus is not limitative of the present invention, and wherein:

FIG. 1 is a schematic view of a conventional heat dissipating apparatus;

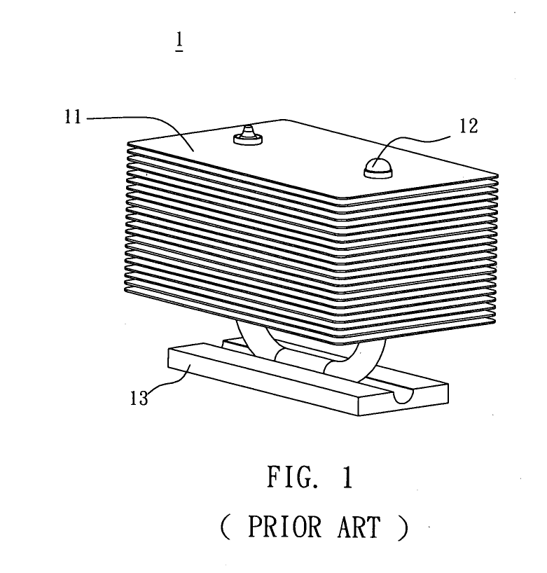

FIG. 2 is an exploded view showing a composite heat dissipating apparatus according to a preferred embodiment of the invention;

FIG. 3 is an assembled view showing the composite heat dissipating apparatus of FIG. 2;

FIG. 4 is an exploded view showing another composite heat dissipating apparatus according to a preferred embodiment of the invention;

FIG. 5 is an assembled view showing the composite heat dissipating apparatus of FIG. 4;

FIG. 6 is an exploded view showing still another composite heat dissipating apparatus according to a preferred embodiment of the invention; and

FIG. 7 is an assembled view showing the composite heat dissipating apparatus of FIG. 6.

### DETAILED DESCRIPTION OF THE INVENTION

The present invention will be apparent from the following detailed description, which proceeds with reference to the accompanying drawings, wherein the same references relate to the same elements.

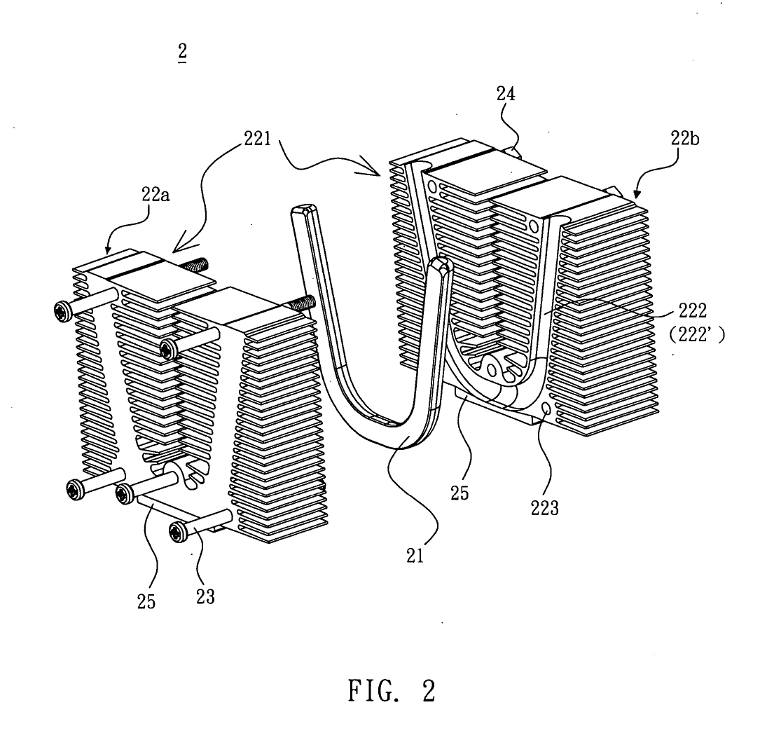

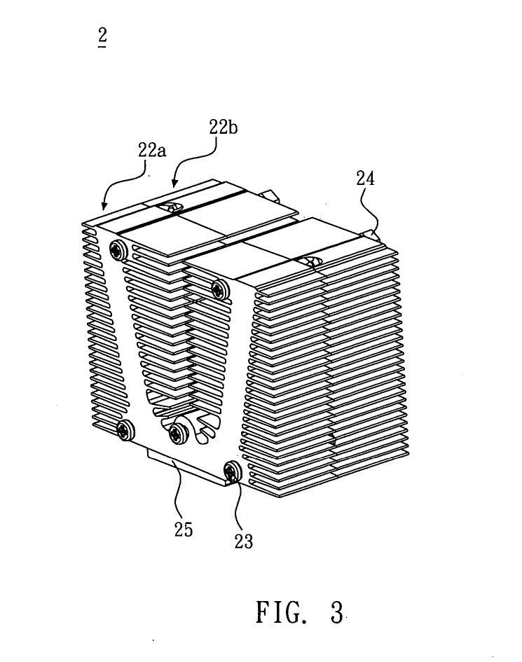

FIG. 2 is an exploded view showing a composite heat dissipating apparatus according to a preferred embodiment of the invention. FIG. 3 is an assembled view showing the composite heat dissipating apparatus of FIG. 2. Referring to FIGS. 2 and 3, a composite heat dissipating apparatus 2 includes a heat pipe 21 and two heat sinks 22a and 22b. The heat pipe 21 may contact a heat source (not shown) through a base 25, or directly contact the heat source so as to transfer the heat generated by the heat source to the heat sinks 22a and 22b directly and then the heat sinks 22a and 22b dissipate the heat out to the exterior. Herein, the heat source may be an electrical element, such as a CPU (Central Processing Unit), transistor, server, advanced graphics card, hard disk, power supply, vehicle control system, multimedia electronic mechanism, wireless base transceiver station, advance game boy (PS3, XBOX, Nintendo), or the like.

The heat sinks 22a and 22b are connected to each other. A space 222 for accommodating the heat pipe 21 therein is formed at a connection 221. The heat pipe 21 of this embodiment is U-shaped, C-shaped, lengthwise-shaped, M-shaped or has any other shapes according to different system requirements. In addition, the cross-sectional area of the heat pipe 21 in this embodiment has a circular shape, or may have an elliptic shape, a semi-circular shape, a rectangular shape, a triangular shape, a tetragonal shape, a trapezoidal shape, a regular polygonal shape or an irregular polygonal shape.

In addition, the heat pipe 21 contains a working fluid for heat transfer, and an inner wall of the heat pipe 21 has a capillary structure. The working manner of the heat pipe 21 is described in the following. When one end (i.e., the evaporating end) of the heat pipe 21 is heated, the working fluid in the heat pipe 21 absorbs heat and is then evaporated. Then, the evaporated working fluid condenses into the liquid at the other end (i.e., the condensing end) of the heat pipe 21 and releases heat energy. At this time, the fluid flows back to the evaporating end through the capillary structure on the inner wall. The operations are repeated such that the heat dissipating effect is achieved.

The heat sinks 22a and 22b may be the same or different from each other. In this embodiment, the two heat sinks 22a and 22b are the same and each heat sink has a plurality of fins arranged in a horizontal distribution, a vertical distribution, a slant distribution, a radial distribution, or other distributions. In addition, the heat sinks 22a and 22b are individually integrally formed as a single piece by way of, for example, aluminum extrusion. The space 222 at the connection 221 between the two heat sinks 22a and 22b is formed by slots 222′ of the two heat sinks 22a and 22b. The shape of the space 222 corresponds to that of the heat pipe 21. After the two heat sinks 22a and 22b are connected to each other, the U-shape space 222 formed by the two slots 222′ may contain a U-shape heat pipe 21. Of course, the space 222 may also have a C shape, lengthwise shape, M shape or any other shapes according to the shape of the heat pipe 21. In addition, the space 222 may also be formed by the slot 222′ on one of the heat sink 22a or the heat sink 22b. That is, one of the heat sinks 22a and 22b has the slot 222′, and the other one of the heat sinks 22a and 22b has no slot 222′. After the two heat sinks 22a and 22b are connected to each other, the single slot 222′ forms the space 222 for accommodating the heat pipe 21.

Furthermore, each of the heat sinks 22a and 22b further has several screw holes 223 such that the heat sink 22a and the heat sink 22b are connected to each other via the screws 23 and nuts 24. It is to be noted that the heat sinks 22a and 22b are connected by using the screws 23 and nuts 24 shown in FIGS. 2 and 3. Alternatively, the heat sinks 22a and 22b are connected by riveting, soldering, adhering, embedding, or engaging.

The method of assembling the heat dissipating apparatus 2 of this embodiment will be described in the following. First, the heat pipe 21 is placed in the space 222 formed by the two heat sinks 22a and 22b. Then, a high-pressure machine (not shown) applies a pressure on the two heat sinks 22a and 22b such that the heat pipe 21 tightly contacts the two heat sinks 22a and 22b. Thereafter, the screws 23 and the nuts 24 are used to combine the heat sinks 22a and 22b. Thus, the heat pipe 21 may be disposed between the two heat sinks 22a and 22b so that the composite heat dissipating apparatus 2 is integrated, as shown in FIG. 3. As mentioned hereinabove, because the heat sinks 22a and 22b have the slots 222′ for accommodating and positioning the heat pipe 21, the invention can position the heat pipe 21 and the heat sinks 22a and 22b, and connect the heat pipe 21 to the heat sinks 22a and 22b without using a jig to clamp the heat sinks 22a and 22b or the heat pipe 21. Thus, the assembling processes can be simplified. Furthermore, a grease or a heat conducting material serving as a heat conducting interface can be coated in the space 222 such that the overall heat dissipating efficiency of the composite heat dissipating apparatus 2 may be enhanced. In addition, the composite heat dissipating apparatus 2 of this embodiment may be used in conjunction with a fan such that the heat transferred from the heat sinks 22a and 22b may be dissipated more quickly, and the better dissipating effect can be obtained.

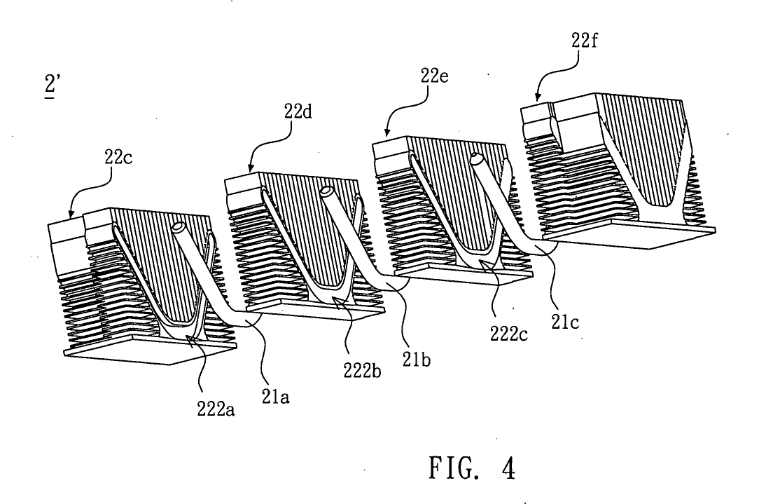

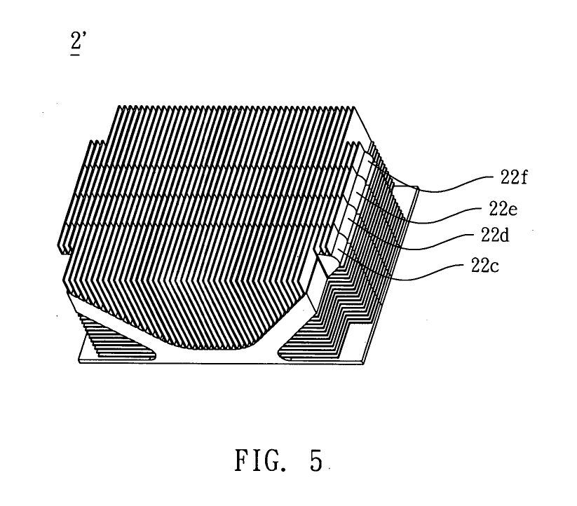

Although the number of the heat pipe 21 in FIG. 2 is one and the number of the heat sinks 22a and 22b is two, the invention is not limited thereto, and the number of the heat pipes or the heat sinks may be selected according to the actual requirement. FIG. 4 is an exploded view showing another composite heat dissipating apparatus according to a preferred embodiment of the invention. FIG. 5 is an assembled view showing the composite heat dissipating apparatus of FIG. 4. Referring to FIGS. 4 and 5, the composite heat dissipating apparatus 2′ includes two heat pipes 21a, 21b and 21c and four heat sinks 22c, 22d, 22e and 22f. Every two adjacent heat sinks for respectively accommodating the heat pipes 21a, 21b and 21c are connected to each other, and spaces 222a, 222b, 222c are formed at connections between every two adjacent heat sinks. The composite heat dissipating apparatus 2′ may be directly placed on the heat source (not shown) and allow the heat pipes 21a, 21b and 21c to directly contact the heat source. Thus, the heat generated by the heat source is directly transferred to the heat sinks 22c, 22d, 22e and 22f and then dissipated to the exterior. Similar to the composite heat dissipating apparatus 2 of FIG. 2, the heat sinks 22c, 22d, 22e and 22f may be the same or different, and the heat pipes 21a, 21b and 21c may be the same or different. The method of assembling the composite heat dissipating apparatus 2′ of this embodiment will be described in the following. First, the heat pipe 21a is placed in the space 222a between the heat sink 22c and the heat sink 22d, the heat pipe 21b is placed in the space 222b between the heat sink 22d and the heat sink 22e, and the heat pipe 21c is placed in the space 222c between the heat sink 22e and the heat sink 22f. Then, a high-pressure machine (not shown) applies a pressure on the heat sinks such that each heat pipe tightly contacts the heat sinks, and the composite heat dissipating apparatus 2′ is integrated, as shown in FIG. 5. In addition, a grease or a heat conducting material serving as a heat conducting interface is coated in the spaces 222a, 222b and 222c, which are formed by the heat sinks 22c, 22d, 22e and 22f, such that the overall heat dissipating efficiency is enhanced.

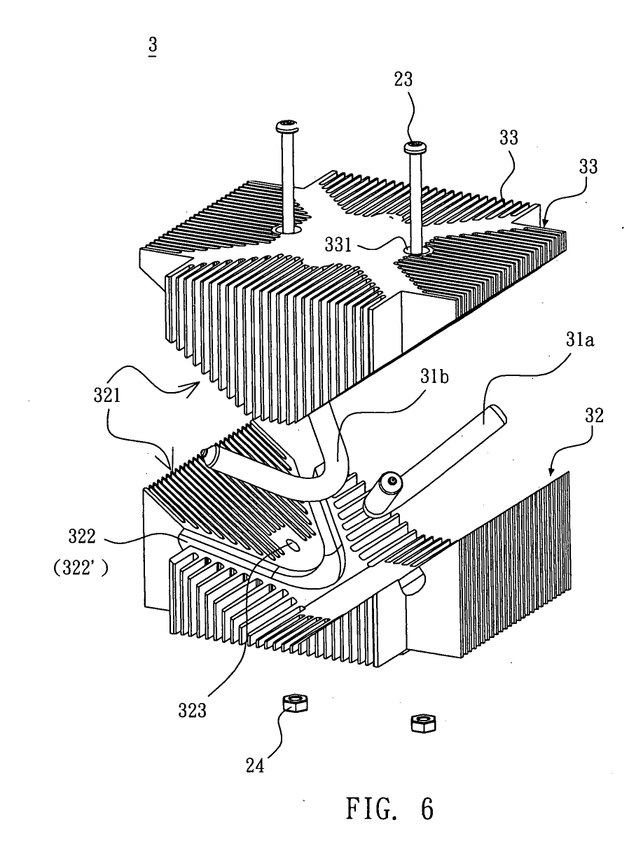

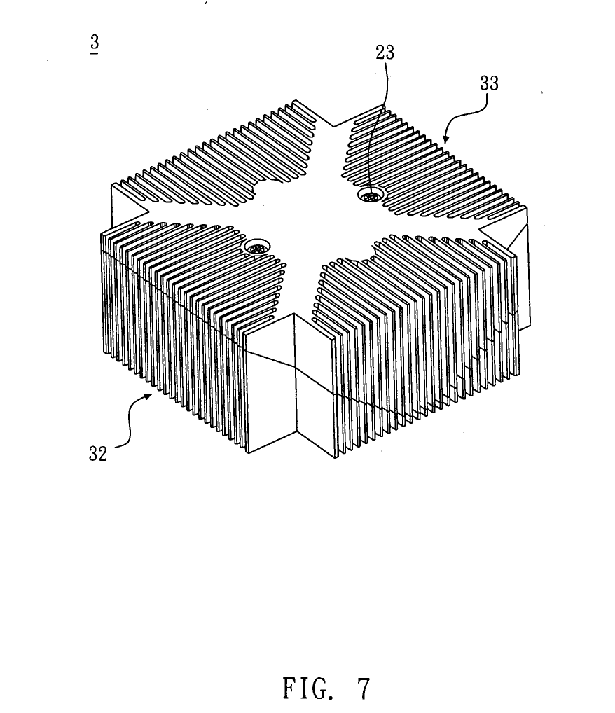

FIG. 6 is an exploded view showing still another composite heat dissipating apparatus according to a preferred embodiment of the invention. FIG. 7 is an assembled view showing the composite heat dissipating apparatus of FIG. 6. Referring to FIGS. 6 and 7, the composite heat dissipating apparatus 3 has two heat pipes 31a and 31b, a first heat sink 32 and a second heat sink 33. Herein, the heat pipes 31a and 31b of this embodiment have, but not limited to the U shape. The heat pipes 31a and 31b may be C-shaped, lengthwise-shaped, M-shaped or have any other shapes according to different system requirements. The functions and the structures of the heat pipes 31a, 31b are same as the above heat pipe 21, so detailed descriptions thereof will be omitted.

The first heat sink 32 and the second heat sink 33 may be different from each other, but have the corresponding shapes to facilitate the assembling process. Two spaces 322 for accommodating the two heat pipes 31a and 31b may be formed at a connection 321 between the heat sinks 32 and 33. The first heat sink 32 at the connection 321 has two slots 322′, and the shapes (U-shapes) of the two slots 322′ correspond to those of the heat pipes 31a and 31b. The second heat sink 33 has no slot. That is, the two spaces 322 are formed by the slots 322′ of the first heat sink 32. In addition, the first heat sink 32 and the second heat sink 33 are respectively formed with corresponding screw holes 323 and 331, such that the screws 23 and the nuts 24 can screw and fasten the first heat sink 32 to the second heat sink 33. Of course, the clearances between the heat pipes 31a, 31b and the slots 322′ are usually filled with a grease or other heat conducting materials to enhance the overall heat dissipation efficiency.

In summary, the heat sinks in the composite heat dissipating apparatus of the invention are manufactured by way of aluminum extrusion. As the result, the heat sink formed by aluminum extrusion is cheaper than that formed by the conventional manufacturing process, such as pressing or assembling multiple fins. In addition, the heat pipe is disposed in the space formed between two adjacent heat sinks. As the result, the heat pipe and the heat sinks are easily combined together without extra plating or pressing procedures. Compared to the prior art, the composite heat dissipating apparatus of the invention is manufactured by aluminum extrusion, so that the manufacturing cost is low and the overall weight of the heat dissipating apparatus is lighter because the aluminum is used. Thus, the invention has the light-weight advantage. Furthermore, the space formed by a single heat sink or more than one heat sink corresponds to the shape of the size of the heat pipe, so that the heat sink and the heat pipe can tightly contact each other and the heat conducting area can be enlarged. In addition, the heat pipe itself has the high conductive property than metal blocks, so that the dissipating effect is better than the typical heat sink without using any heat pipe under the same area. In addition, when the aluminum extrusion is performed, the heat sink may be processed in the feature and may be easily glorified. Thus, the composite heat dissipating apparatus of the invention can achieve the effects of simplifying the manufacturing processes, enhancing the production efficiency, reducing the cost, and providing good heat dissipating efficiency.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. A composite heat dissipating apparatus, comprising:
a heat pipe; and
at least two heat sinks, disposed oppositely and connected to each other, wherein a space for accommodating the heat pipe therein is formed at a connection between the two heat sinks, and each of the two heat sinks is integrally formed as a single piece.

2. The apparatus according to claim 1, wherein the heat pipe is U-shaped, C-shaped, lengthwise-shaped, M-shaped or has any other shapes.

3. The apparatus according to claim 1, wherein the heat sinks are respectively formed with slots for forming the space.

4. The apparatus according to claim 1, wherein only one of the heat sinks is formed with a slot for providing the space.

5. The apparatus according to claim 1, wherein the heat sinks are connected by way of riveting, screwing, soldering, adhering, embedding or engaging.

6. The apparatus according to claim 1, wherein the heat pipe contacts the heat sinks tightly by a pressure provided from a high-pressure machine.

7. The apparatus according to claim 1, wherein the heat sinks have same shape or different shapes.

8. The apparatus according to claim 1, wherein each of the heat sinks is integrally formed by way of aluminum extrusion.

9. The apparatus according to claim 1, wherein a grease or a material serving as a heat conducting interface is coated in the space.

10. The apparatus according to claim 1, wherein the heat pipe contacts a heat source through a base or contacts the heat source directly so as to transfer heat generated by the heat source to the heat sinks directly.

11. A composite heat dissipating apparatus, comprising:
a plurality of heat pipes; and
a plurality of heat sinks connected to one another, wherein spaces are formed at connections between every two adjacent heat sinks, and each of the heat sinks is integrally formed as a single piece.

12. The apparatus according to claim 11, wherein the heat pipes are U-shaped, C-shaped, lengthwise shaped, M-shaped, or has any other shapes.

13. The apparatus according to claim 11, wherein each of the heat sinks is formed with a slot for forming the spaces at the connections.

14. The apparatus according to claim 11, wherein only one of the two adjacent heat sinks is formed with a slot for forming the space at the connections.

15. The apparatus according to claim 11, wherein the heat sinks are connected by way of riveting, screwing, soldering, adhering, embedding or engaging.

16. The apparatus according to claim 11, wherein the heat sinks have same shape or different shapes.

17. The apparatus according to claim 11, wherein the heat sinks are integrally formed by way of aluminum extrusion.

18. The apparatus according to claim 11, wherein grease or a material serving as a heat conducting interface is coated in the spaces.

19. The apparatus according to claim 11, wherein the heat pipes contact a heat source through a base or contact the heat source directly so as to transfer heat generated by the heat source to the heat sinks directly.

20. A composite heat dissipating apparatus, comprising:
at least two heat pipes; and
a first heat sink and a second heat sink, which have different shapes and are connected to each another, wherein at least two spaces for respectively accommodating the at least two heat pipes therein are formed at a connection between the first heat sink and the second heat sink, and each of the first heat sink and the second heat sink is integrally formed as a single piece.
